(19) United States
(12) Patent Application Publication
(10) Pub. No.: US 2011/0248315 A1
(43) Pub. Date: Oct. 13, 2011

(54) STRUCTURED PILLAR ELECTRODES

(75) Inventors: Chang-Yong Nam, Upton, NY (US); Charles T. Black, New York, NY (US); Ioana R. Gearba, Austin, TX (US); Jonathan Edward Allen, Medford, NY (US)

(73) Assignee: BROOKHAVEN SCIENCE ASSOCIATES, Upton, NY (US)

(21) Appl. No.: 13/058,891

(22) PCT Filed: Aug. 14, 2009
(86) PCT No.: PCT/US2009/053893

§ 371 Date: Apr. 18, 2011

Related U.S. Application Data
(60) Provisional application No. 61/088,826, filed on Aug. 14, 2008.

(51) Int. Cl. H01L 31/0336; H01L 31/18

(52) U.S. Cl. 257/184; 438/94; 257/E31.005; 257/E31.124

(57) ABSTRACT

An electrode comprising a plurality of structured pillars dispersed across a base contact and its method of manufacture are described. In one embodiment the structured pillars are columnar structures having a circular cross-section and are dispersed across the base surface as a uniformly spaced two-dimensional array. The height, diameter, and separation of the structured pillars are preferably on the nanometer scale and, hence, electrodes comprising the pillars are identified as nanostructured pillar electrodes. The nanostructured pillars may be formed, for example, by deposition into or etching through a surface template using standard lithography processes. Structured pillar electrodes offer a number of advantages when incorporated into optoelectronic devices such as photovoltaic cells. These include improved charge collection efficiency via a reduction in the carrier transport distance and an increase in electrode-photoactive layer interface surface area. These improvements contribute to an increase in the power conversion efficiency of photovoltaic devices.

### CROSS-REFERENCE TO RELATED APPLICATIONS

This application claims priority to U.S. Provisional Patent Application No. 61/088,826 which was filed on Aug. 14, 2008 and is incorporated by reference as if fully set forth in this specification.

### STATEMENT OF GOVERNMENT LICENSE RIGHTS

The present invention was made with government support under Grant No. DE-AC02-98CH10886 awarded by the U.S. Department of Energy, Division of Chemical and Material Sciences. The United States government has certain rights in the invention.

### BACKGROUND OF THE INVENTION

I. Field of the Invention

This invention relates generally to structured electrodes. In particular, the present invention relates to electrodes having vertically aligned pillars dispersed across a horizontal base contact. The invention also relates to the manufacture of such structured pillar electrodes and their use in electronic devices such as solar cells.

II. Background of the Related Art

A photovoltaic cell is an energy conversion device capable of converting electromagnetic radiation into electrical energy. When the process involves the conversion of sunlight directly into electricity, the device is commonly referred to as a solar cell. The energy conversion process is based on the photovoltaic (PV) effect in which the absorption of incident photons on an active layer creates electron-hole pairs. Upon introduction of an internal or external electric field, the generated charge carriers migrate in opposite directions along a conducting path to create an electrical current. A number of materials in both bulk and thin film form have been used to fabricate PV cells with a power conversion efficiency (PCE) which depends on the type of material, its microstructure, and the overall construction of the PV cell. The science and technology of PV devices has received considerable attention, being the subject of numerous books, journal, and review articles including, for example, “Basic Research Needs for Solar Energy Utilization,” a report on the Basic Energy Sciences Workshop on Solar Energy Utilization held Apr. 18-21, 2005 which is incorporated by reference as if fully set forth in this specification.

Materials which have been investigated for use as the photoactive medium in PV devices include, for example, cadmium telluride (CdTe), copper indium selenide (CuInSe), gallium arsenide (GaAs), and silicon (Si). From among these, Si is the most common, typically being used either as a bulk single crystal, as a polycrystalline material, or in thin film form. While the majority of silicon-based PV cells on the market today are fabricated from crystalline-Si technology, Si-based thin film PV cells offer several advantages including more efficient utilization of source material, the capability for conformal coverage of the underlying substrate, and comparatively lower manufacturing costs. The PCE of microcrystalline and amorphous Si thin film PV cells has improved steadily, with the highest reported values being in the range of 10 to 20%. Despite the continued progression of Si thin film PV cells, their material and manufacturing costs remain relatively high, making Si-based PV power production uncompetitive with conventional fossil fuel-based energy sources. Contributing factors include the need for large Si film thicknesses for efficient light absorption (≧200 μm), as well as their complex and expensive (requiring both time and energy) fabrication processes. This typically involves sequential deposition of a plurality of materials in one or more evacuated process chambers.

An attractive alternative to Si-based PV devices which has recently emerged involves the use of an organic layer as the active medium. Compared to Si-based PV devices, organic PV cells use lower-cost materials and simpler solution-based fabrication techniques. Generally, organic PV cells are formed with an organic film comprised of a photo-active polymer or some other small molecule which is layered between opposing planar electrodes. However, planar organic heterojunctions are generally inefficient as a photo-active layer since the diffusion length of generated bound electron-hole pairs (i.e., excitons), which later dissociate into free charge carriers, is much smaller than the optical absorption length. Improvements in device performance have been obtained by using an intermixed layer of electron-donating molecules (n-type) and electron-accepting molecules (p-type). The blended layer typically comprises a phase segregated mixture of donor and acceptor materials which is known as a bulk heterojunction. Experimental results have shown that bulk heterojunction PV devices have a higher conversion efficiency than planar devices due to the interpenetrating nature of the donor-acceptor interface. Examples of optoelectronic devices having a bulk heterojunction and their method of manufacture are provided by U.S. Pat. No. 7,435,617 to Shtein, et al. and U.S. Patent Application Publ. No. 2008/0012005 to Yang, et al. which are incorporated by reference as if fully set forth in this specification.

Despite the potential of organic bulk heterojunction PVs, the highest PCE of these devices is only ˜3 to 5%, a value which, despite the lower manufacturing costs, is still too low for commercial applications. The low PCE is attributed primarily to (1) the intrinsically low carrier mobility of organic semiconductors and related material blends (typically several orders of magnitude lower than those of equivalent inorganic materials) and (2) the poor absorption band overlap between the organic semiconductor and the incident solar spectrum. Recent attempts to overcome these limitations have included replacing an organic semiconductor component with inorganic nanoparticles to create an active layer comprised of an organic-inorganic hybrid composite. An example is described in U.S. Patent Application Publ. No. 2005/0061363 to Ginley, et al., which is incorporated by reference as if fully set forth in this specification. Another approach involves using an organic active layer component with a better absorption overlap with the solar spectrum. An example involves using a C₇₀ derivative as the n-type material in a bulk heterojunction as disclosed by X. Wang, et al. in “Enhanced Photocurrent Spectral Response in Low-Bandgap Polyfluorene and C₇₀-Derivative-Based Solar Cell,” Advanced Functional Materials, 15, 1665 (2005) which is incorporated by reference as if fully set forth in this specification.

Despite the improvements in organic PV devices achieved using these approaches, the low intrinsic carrier mobility and comparatively larger optical absorption length of organic semiconductors severely limits the efficiency by which positive and negative charges can be separated and transported to their respective electrodes to create a photocurrent. The small exciton diffusion length of organic semiconductors requires that the generated excitons be located near a heterojunction in order for them to be efficiently dissociated into free charge carriers by avoiding recombination. In a conventional bilayer device structure, this requirement generally favors the use of thin photoactive layers (i.e., thickness comparable to an exciton diffusion length of ˜5-10 nm) such that there is a greater probability that excitons will migrate to the heterojunction area, dissociate into free carriers, and subsequently transport to their respective electrodes. However, a thinner photoactive layer means that there is a lower probability that incident photons will be fully absorbed considering that the optical absorption length of an organic active layer is generally 100-200 nm whereas the exciton diffusion length is typically on the order of 5-10 nm.

### SUMMARY OF THE INVENTION

Having recognized the above and other considerations, the inventors determined that there is a continuing need to develop structures which address the inefficiencies associated with charge generation and transport in photovoltaic devices. In particular, there is a need for photovoltaic devices with significantly higher power conversion efficiency gains than have been realized to date. In view of the above-described problems, needs, and goals, some embodiments of the present invention provide an electrode having structured pillars formed on its surface and methods for their manufacture. The pillars are substantially columnar structures having a predetermined height, cross-sectional shape, and spatial arrangement on the electrode surface. When distributed across the electrode surface, the structured pillars appear analogous to fingers extending into the photoactive material.

Structured pillar electrodes are especially advantageous when incorporated into photovoltaic devices since their increased electrode surface area and the proximity of the pillars to sites where free charge carriers may be generated promotes more efficient collection of charge carriers. Either one or more electrodes within the photovoltaic device may include structured pillars depending on the design requirements. The overall electrode structure preferably comprises a planar base of a conducting material with structured pillars dispersed across its surface.

In one embodiment the structured pillars are approximately equal in length, cross-sectional diameter, and shape and are spaced equidistant from each other in the form of a two-dimensional array. The structured pillars are preferably perpendicular to the plane of the base, have a columnar shape, and a circular cross-section. The length to diameter ratio of the pillars is preferably greater than 0.5 making them substantially columnar. However, the size distribution, shape, and spacing of the pillars is not so limited. Uneven shape distributions and irregular spacings may also be used. The cross-section may be elliptical, square, rectangular, pentagonal, hexagonal, octagonal, or any shape as is well-known in the art. The cross-sectional diameter of each pillar is preferably 1 to 100 nm such that they are considered to be nanostructured pillars. In a preferred embodiment the cross-sectional diameter is between 20 to 30 nm. In still another embodiment the cross-sectional diameter is 10% to 20% of the thickness of the photoactive layer. The total length of the structured pillars is preferably less than or equal to half the thickness of the photoactive layer. In a preferred embodiment the length of the structured pillars is between 20 and 100 nm. The separation between individual structured pillars preferably ranges from greater than 20 nm to less than or equal to 500 nm.

In another embodiment the structured pillars are preferably formed from a conductive material having a low electrical resistivity or, equivalently, a high electrical conductivity. This includes all transition metals which fall within the d-block of the periodic table which includes elements between columns II and III, inclusive. Some preferred examples include metals such as aluminum (Al), silver (Ag), gold (Au), copper (Cu), calcium (Ca), magnesium (Mg), indium (In), or gallium (Ga)—In alloys. The structured pillars preferably have a resistivity of less than 1×10⁻⁴ Ohm-cm. When incorporated in a photovoltaic device, it is preferable that at least one structured pillar electrode be transparent. The transparent electrode is preferably fabricated from indium tin oxide (ITO) coated with poly(3,4-ethylenedioxythiophene: poly(styrene sulfate)) (PEDOT:PSS) or ITO coated with fluorinated tin oxide (SnO₂:F). In still another embodiment the electrode may comprise zinc oxide, titanium oxide, vanadium oxide, molybdenum oxide, gallium nitride, carbon nanotubes, or insulating silicon oxide coated with a transparent metal film.

The structured pillar electrodes may be fabricated using any method which is well-known in the art. This includes both top-down and bottom-up approaches. Examples of top-down methods include standard photolithographic techniques such as deposition through a removable surface template or etching of selected regions of a thin film through openings in a removable mask. Examples of bottom-up approaches include vapor-liquid-solid growth of nanowires, electroplating into a mesoporous template, or processes involving self-assembly.

An additional embodiment relates to an optoelectronic device having at least one structured pillar electrode. The optoelectronic device is preferably a photovoltaic device, but may also be a light emitting diode, a photodetector, or a phototransistor. The optoelectronic device preferably comprises at least a bottom electrode, a photoactive layer, and a top electrode. In a preferred embodiment at least one of the bottom electrode and the top electrode is a structured pillar electrode. The photoactive layer preferably comprises a heterojunction which may be a bulk heterojunction, a planar heterojunction, or an ordered heterojunction.

Still another embodiment relates to methods of forming an optoelectronic device comprising at least one structured pillar electrode. One method involves initially depositing a base layer onto a substrate followed by creation of a mask onto the base layer. Structured pillars are then formed through openings in the mask. A film of a photoactive layer having a heterojunction is formed onto the base layer having structured pillars. The photoactive layer may be formed, for example, by solution processing. In one embodiment the mask comprises a self-assembled polymer template formed from a diblock copolymer film. In another embodiment the mask comprises an anodized aluminum oxide membrane with self-assembled hexagonal array of holes. Alternatively, the mask may be formed using processes such as photolithography, electron beam lithography, dip-pen nanolithography, and ion beam lithography. The pillars may be formed by deposition through or etching away regions of the base layer exposed by the openings in the mask.

In another embodiment, an array of structured pillars is formed by anodizing the surface of a bottom electrode to form an oxidized surface layer comprising self-organized pores followed by selectively stripping the oxidized surface layer to produce a pattern on the surface of the bottom electrode. In this embodiment the bottom electrode may comprise, for example, Al, titanium (Ti), or zinc (Zn). In an exemplary embodiment the bottom electrode comprises Al and electrochemical anodization of the Al substrate in an electrolyte under the proper conditions produces a self-assembled three-dimensional array of nanometer-scale pores within an anodized aluminum oxide layer. Anodization is typically performed in an acidic solution such as sulfuric acid, oxalic acid, or phosphoric acid. This produces an ordered array of pores in an aluminum oxide matrix having a mean pore diameter of between 10 and 300 nm and a mean center-to-center separation of between 50 and 400 nm. After stripping the oxide layer, the remaining Al surface consists of tapered Al pillars spaced approximately 50-400 nm apart. The oxide layer may be removed by immersion in an acid which selectively removes the oxidized surface layer without etching the underlying bottom electrode. In one embodiment selective etching is performed using phosphoric acid. In another embodiment etching may be accomplished by exposure to a plasma. The spacing, height, and diameter of the pillars can be modified through variations in the anodization conditions. The thus-formed pillars may be protected from further oxidation by, for example, deposition of a passivating surface layer.

Yet another embodiment relates to a method of forming an optoelectronic device comprising a top structured pillar electrode. The method comprises initially depositing a bottom electrode onto a substrate followed by the formation of a film of a photoactive layer having a heterojunction on the bottom electrode. Recessions which will become structured pillars upon filling are then formed in the photoactive layer. The recessions may be formed by etching through a mask or imprinting a stamp having the desired pattern. The mask may be formed using processes analogous to those described above for a bottom structured pillar electrode. Deposition onto the photoactive layer fills the recessions to produce structured pillars. Continued deposition results in the formation of a top electrode on the pillars and the photoactive layer.

### BRIEF DESCRIPTION OF THE DRAWINGS

FIG. 1A is a cross-sectional schematic of a conventional photovoltaic device having a photoactive layer with a planar heterojunction;

FIG. 1B is a cross-sectional schematic of a conventional photovoltaic device in which the photoactive layer comprises a bulk heterojunction;

FIG. 1C is a cross-sectional schematic of a conventional photovoltaic device in which the photoactive layer comprises an ordered heterojunction;

FIG. 2A shows a photovoltaic device comprising a planar heterojunction and structured pillar electrodes;

FIG. 2B shows a photovoltaic device comprising a bulk heterojunction and structured pillar electrodes;

FIG. 3 shows a sequence of steps in which structured pillar electrodes are formed by anodization of a metal substrate, such as aluminum, zinc or titanium followed by stripping the oxide layer;

FIG. 4 shows a sequence of steps in which structured pillar electrodes are formed by etching through a surface template; and

FIG. 5 shows a sequence of steps in which structured pillar electrodes are formed by deposition through openings in a surface template.

### DETAILED DESCRIPTION OF THE INVENTION

The above and other objectives of the invention will become more apparent from the following description and illustrative embodiments which are described in detail with reference to the accompanying drawings. Similar elements in each Figure are designated by like reference numbers and, hence, subsequent detailed descriptions thereof may be omitted for brevity. In the interest of clarity, in describing the embodiments of the present invention, the following terms and acronyms are defined as provided below.

### Acronyms

CVD: Chemical Vapor Deposition
ITO: Indium Tin Oxide
LED: Light Emitting Diode
FTO: Fluorinated Tin Oxide
MBE: Molecular Beam Epitaxy
PEDOT:PSS: poly(3,4-ethylenedioxythiophen:poly(styrene sulfanate))
PCE: Power Conversion Efficiency
PV: Photovoltaic
PVD: Physical Vapor Deposition
RIE: Reactive Ion Etching

### Definitions

Acceptor: A dopant atom which, when added to an inorganic semiconductor, can form p-type regions. In an organic semiconductor an acceptor is generally identified as a material which absorbs incident photons to produce mobile excitons. When an exciton migrates to a junction between an organic acceptor and donor, the hole remains in the acceptor whereas the electron is transferred to the donor.
Donor: A dopant atom which, when added to an inorganic semiconductor, can form n-type regions. In an organic semiconductor a donor is generally identified as a material which accepts electrons.
Exciton: The bound state of an electron and hole pair in a material. An exciton is capable of transporting energy without transporting a net charge.
Heterojunction: An interface or junction formed between dissimilar materials.
Inorganic: A material or compound which does not contain an organic compound.
n-type: A semiconductor for which the predominant charge carriers responsible for electrical conduction are electrons. Normally, donor impurity atoms give rise to the excess electrons.
Optoelectronic: The study and application of electronic devices which source, detect, and control electromagnetic radiation. This includes visible and invisible forms such as gamma rays, X-rays, ultraviolet, visible, and infrared radiation. Examples of optoelectronic devices include photovoltaic devices, photodetectors, phototransistors, and light emitting diodes.
Photovoltaics: The field of technology and research related to the conversion of electromagnetic radiation (e.g., sunlight) to electrical energy.
p-type: A semiconductor for which the predominant charge carriers responsible for electrical conduction are holes. Normally, acceptor impurity atoms give rise to the excess holes.

The embodiments of the present invention were devised based on the discovery that the properties and performance of electronic devices, particularly photovoltaic devices can be significantly improved by employing at least one electrode comprising structured pillars. By using structured pillar electrodes, the electrode itself can be placed in close proximity to the interface(s) in the photoactive layer, thereby increasing the probability that the positive and negative charges generated by an incident photon will migrate to their respective electrodes to produce an electrical current. The interpenetrating nature of pillar electrodes means that a thicker photoactive layer can be used and, hence, a larger proportion of the photoactive layer is available for absorption of incident photons. The combination of these two primary features results in an increase in both the probability that electromagnetic radiation incident upon the active layer will be absorbed and the probability that the thus-generated charge carriers will be able to migrate to the appropriate electrode.

### I. Photovoltaic Device Structure

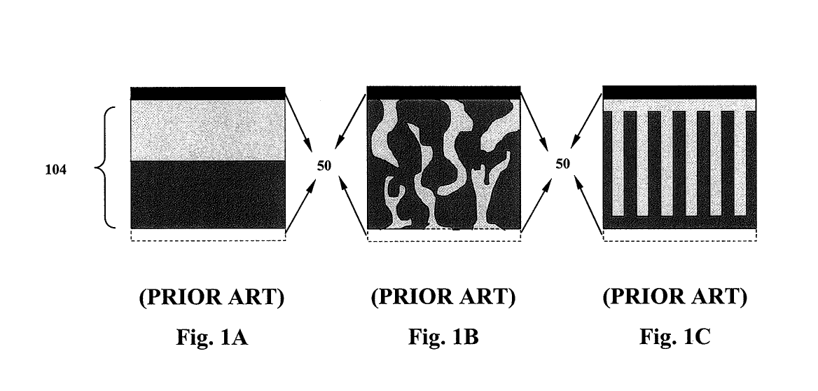

Although this specification focuses primarily on applications involving photovoltaic (PV) devices, it is to be understood that the structured pillar electrodes which are disclosed and described may be employed in a wide variety of electronic or optoelectronic devices. This includes, but is not limited to, light emitting devices (LEDs), phototransistors, and photodetectors. The use of structured pillar electrodes in PV devices is merely provided as an exemplary embodiment, being used to describe what is currently considered to be the best mode of practicing the invention. Conventional PV devices are comprised of three main components: (1) a bottom electrical contact, (2) a layer comprising the photoactive material(s), and (3) a top electrical contact. Examples of conventional PV devices comprising a planar, bulk, and ordered heterojunction as the photoactive layer are shown in FIGS. 1A, 1B, and 1C, respectively. In FIGS. 1A-C, the top and bottom electrodes are identified as component (50) whereas a photoactive layer (104) is sandwiched between each set of top and bottom electrodes (50).

A planar heterojunction (FIG. 1A) is formed between two materials which are usually deposited sequentially onto a planar substrate, one on top of the other such that the interface between them forms a two-dimensional plane. A bulk heterojunction is formed from an intermixed, phase-segregated blend of two materials as illustrated in FIG. 1B. An ordered heterojunction may be formed when structures such as, for example, an ordered array of columnar pores are formed in one photoactive material (e.g., a metal oxide or higher melting point polymer) and a solution of a polymer or other small molecule is poured into this mold to form the structure illustrated in FIG. 1C. The bottom and top electrodes (50) provide a medium for delivering the current or voltage generated by the photoactive layer (104). When two electrodes (50) are present, as is illustrated in FIGS. 1A-C, the overall structure of the device determines which electrode is the cathode and which is the anode. The same material may be a cathode in one device and an anode in another device.

PV devices are generally formed by initially depositing a bottom electrode (50) onto a suitable substrate which may be any insulating material as is well-known in the art such as a glass, ceramic, plastic, polyethylene terephthalate or any other related material. If light is to be incident from the bottom, it is preferable that both the substrate and bottom electrode (50) be transparent. It is to be understood, however, that the degree of transparency may vary and that the substrate and bottom electrode (50) may be translucent. When there is more than one electrode, it is preferable that at least one of the electrodes be transparent. The transparent electrode may be made from a material such as indium tin oxide (ITO) either alone or coated with poly(3,4-ethylenedioxythiophen:poly(styrene sulfonate)) (PEDOT:PSS), or fluorinated tin oxide (FTO). In still another embodiment the transparent electrode may comprise aluminum-zinc-oxide, zinc oxide, titanium oxide, vanadium oxide, molybdenum oxide, gallium nitride, carbon nanotubes, insulating silicon oxide coated with a transparent metal film, or any combination of these.

In a preferred embodiment the electrodes (50) are formed from an electrically conductive material which includes metals or metal alloys. Alternatively, the electrodes (50) can be constructed from materials having metal-like properties such as some metal oxides. Some examples include gold (Au), silver (Ag), aluminum (Al), copper (Cu), calcium (Ca), magnesium (Mg), indium (In), gallium (Ga)—In alloys, or combinations thereof. Within this specification an electrically conductive material is defined as a material having an electrical resistivity of less than 10⁻⁴ Ohm-cm. When one of the electrodes (50) is formed from a metal, it generally serves as the anode. This is the case even when the photoactive layer comprises a bulk heterojunction and both the electron-accepting and hole-transporting materials are in contact with both electrodes. The bottom and top electrodes (50) may be formed using any of a wide variety of thin film deposition processes which are well-known in the art. These include, but are not limited to, thermal evaporation, chemical vapor deposition (CVD), physical vapor deposition (PVD), or electrodeposition. In an alternative embodiment the electrodes (50) may be formed through solution processing of metallic nanocrystals.

Deposition of the bottom electrode (50) is followed by formation of a photoactive layer (104) comprised of one or more photoactive materials which may be either inorganic, organic, or a composite of organic and inorganic materials. The photoactive material absorbs electromagnetic radiation (e.g., sunlight) and generates bound electron-hole pairs (i.e., excitons) over a wavelength range corresponding to the band gap of the photoactive material. The photoactive layer comprises either a homojunction (a single material having a junction formed due to doping with different carrier types) or a heterojunction (formed from two types of materials with different carrier types). The materials constituting the homojunction or heterojunction preferably have valence and conduction band energy levels which are sufficiently offset to promote efficient free charge carrier separation at the junctions within the photoactive layer (104). A larger band offset provides a larger driving force for charge separation, thereby ensuring minimal recombination losses.

The photoactive material may be any material which facilitates the absorption of electromagnetic radiation and generation of charge carriers. This includes, for example, organic and/or inorganic materials, organometallic compounds, polymers, and/or other small molecules. Examples of inorganic materials include group-IV, III-V, or II-VI semiconductors. This includes, for example, silicon (Si), germanium (Ge), carbon (C), tin (Sn), lead (Pb), gallium arsenide (GaAs), indium phosphide (InP), indium nitride (InN), indium arsenide (InAs), cadmium selenide (CdSe), cadmium sulfide (CdS), lead sulfide (PbS), lead telluride (PbTe), zinc sulfide (ZnS), and cadmium telluride (CdTe). The semiconductor used may also be an alloy of one or more semiconductors such as SiGe, GaInAs, or CdInSe and is generally suitably doped to form separate n-type or p-type regions. Chemical routes for making doped and undoped group-IV semiconductor nanocrystals have been described, for example, in U.S. Pat. Nos. 6,855,204 and 7,267,721, both of which are to Kauzlarich, et al. and, along with the references cited therein, are incorporated by reference as if fully set forth in this specification.

In another embodiment, inorganic metal oxide particles such as, for example, Cu₂O, TiO₂, or ZnO which exhibit suitable light-absorption and photo-active properties are used as the photoactive medium. An example is provided by U.S. Pat. No. 6,849,798 to Mitra, et al. which discloses the inclusion of a nanocrystalline layer of Cu₂O in an organic solar cell. Another example is U.S. Patent Application Publ. No. 2006/0032530 to Afzali-Ardakani, et al. which discloses an organic semiconductor device comprising soluble semiconducting inorganic nanocrystals interspersed within an organic layer of pentacene. Both of the aforementioned are incorporated by reference as if fully set forth in this specification.

Small molecules are non-polymer materials having a specified chemical formula and a defined molecular weight whereas the molecular weight of a polymer having a defined chemical formula may vary. Small molecules may include repeating units and may be incorporated into a polymer. Organic materials used as the photoactive layer are preferably those having a high level of conjugation. Such materials include, for example, poly(3-hexylthiophene); poly(p-phenylene vinylene); poly(9,9′-dioctylfluor-co-benzothiadiazole) F8BT; fullerenes; (6,6)-phenyl-C61-butyric acid methyl ester or poly(2-methoxy-5-(3′,7′-dimethyloctyloxy))-1,4-phenylene-vinylene; and poly[2,6-(4,4-bis-(2-ethylhexyl)-4H-cyclopenta[2,1-b;3,4-b′]-dithiophene)-alt-4,7-(2,1,3-benzothiadiazole).

The photoactive layer (104) may be deposited using any technique which is well-known in the art. In one embodiment of the invention, this includes processes such as spin-casting, dip coating, ink jet printing, screen printing, or micromolding. The thickness is preferably 100 nm up to 1 μm, but is not so limited and may be controlled, for example, through changes in the viscosity of the solvent used. Deposition of the photoactive layer (104) is followed by the formation of a top electrode (50) which is deposited in a manner analogous to the bottom electrode (50). The photovoltaic device, its constituents, and method of manufacture as described above will be used to describe the structure, function, and advantages of structured pillar electrodes in the sections that follow.

### II. Structured Pillar Electrodes

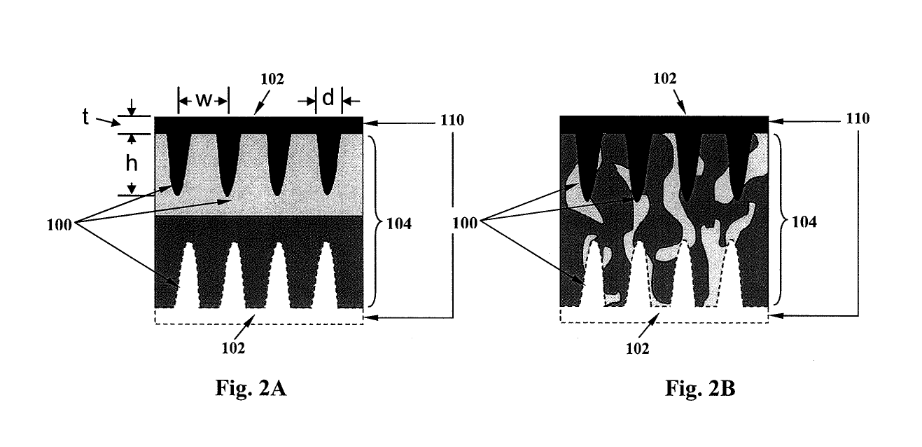

The present invention replaces one or more electrodes (50) in the PV device described in Section I with a structured pillar electrode. The overall structure of the electrode as well as possible variants will now be described with reference to FIGS. 2A and 2B which show cross-sectional schematics of planar heterojunction and bulk heterojunction PV devices, respectively, comprising structured pillar electrodes (110). The structured pillar electrodes (110) include a horizontal base (102) on which an evenly spaced array of pillars (100) is situated. The pillars (100) are substantially columnar in shape, being vertically aligned such that they protrude from the base surface (102) into the photoactive layer (104). The pillars (100) typically have a circular cross-section and a length to diameter ratio which is substantially larger than 0.5. The cross-section of the pillars (100) may, however, take on any shape which is well-known in the art such as a pyramidal, square, rectangular, hexagonal, or octagonal cross-section.

The horizontal base (102) has a thickness (t) and the pillars (100) are preferably uniformly dispersed across the base surface (102) in the form of a two-dimensional grid. The arrangement and spacing (w) of the thus-formed grid is designed based on the properties of the photoactive layer (104). The spacing (w), cross-sectional shape, and height (h) of the structured pillars (100) is designed to maximize the absorption of incident photons and separation of generated charge characters. The two-dimensional surface grid may be that of a square, a hexagon, or any other suitable surface lattice which is well-known in the art. Alternatively the distribution of pillars (100) may be random instead of ordered. When designing the spacing (w) between pillars (100), consideration is given to characteristics such as the grain size, degree of intermixing and phase segregation, as well as the thickness of the photoactive layer (104). Typically the separation (w) between adjacent pillars (100) is about 20 nm to about 500 nm. For organic photoactive layers the separation distance (w) is preferably between about 20 nm to 30 nm.

The length (h) of each pillar (100), which is defined as the vertical distance from the electrode base (102) to the tip of the pillar (100) is preferably such that it facilitates efficient conduction of charge carriers. Generated bound electron-hole pairs or excitons should separate into free charge carriers prior to reaching a pillar (100) in order for current to flow. The pillar (100) length (h) is preferably tailored to match the optical absorption length of the photoactive material (104). Although the exact length (h) depends on the composition and structure of the PV cell, in a preferred embodiment the pillar (100) length (h) is generally about 20 nm to about 100 nm. In another embodiment the length (h) of the pillar (100) is approximately half of the thickness of the photoactive layer (104). The length and alignment of the top and/or bottom structured pillars should be such that they do not come into contact with the opposing electrode. When the structured pillars (100) have nanometer-scale dimensions they are generally referred to as nanostructured pillar electrodes.

The cross-sectional diameter (d) of each pillar (100) is preferably large enough such that the electrical resistance is not negatively impacted, yet small enough to occupy only a small fraction of the bulk of the photoactive layer (104). In one embodiment the diameter (d) is preferably about 10% to 20% of the thickness of the photoactive layer (104). For a PV device with an organic photoactive layer the pillar (100) diameter is preferably about 20 nm to 30 nm. The size distribution need not be uniform and there may be some variation in the actual diameter (d) among adjacent pillars (100) or between groups of pillars (100). It is preferable that the diameter and position of the pillars be such that there is some separation between individual structured pillars (i.e., adjacent pillars do not come into contact with each other).

The position of the structured pillar electrode (110) relative to the photoactive layer (104) has no effect on the electrode's effectiveness or function as a conducting medium. Whether a specific structured pillar electrode (110) acts as an electron-acceptor or hole-acceptor is dependent on the type of photoactive materials used to form the heterojunction, the manner in which they are assembled, as well as the materials used to form each structured pillar electrode (110). Within this specification, reference to a “top” or “bottom” electrode merely refers to the position of the structured pillar electrode (110) during fabrication of the PV device and does not relate to the status of the electrode as either an electron-acceptor or hole-acceptor.

When structured pillar electrodes are used on both top and bottom electrodes, structured pillars on each electrode may be vertically aligned or offset from each other. Furthermore, there may be variations in the spacing, diameter, length, and shape of the structured pillars on the top and bottom electrodes. The top and bottom structured pillars may be vertically separated by a gap as shown in FIGS. 2A-B or they may be horizontally offset and vertically interpenetrating.

### III. Structured Pillar Fabrication Methods

Embodiments describing methods of forming structured pillar electrodes will now be described in detail with reference to FIGS. 2-5. It is to be understood, however, that these embodiments are merely exemplary and are used to describe possible methods of forming structured pillar electrodes. There are many possible variations which do not deviate from the spirit and scope of the present invention and these variations may serve as functional equivalents. Examples of microfabrication and nanofabrication techniques which are well-known in the art include, but are not limited to standard photolithography techniques as well as electron beam lithography, dip-pen nanolithography, ion beam lithography, and self-assembly processing techniques. These processes may be combined with one or more thin film growth and/or etching processes to form pillars having the desired shape, size, and separation distance.

The manner in which a structured pillar electrode (110) is fabricated depends on whether it is to be used as a bottom electrode or top electrode. When used as a bottom electrode there is greater flexibility and selection in the type of fabrication method used to form the structured pillars (100). One method for forming structured pillar electrodes for the bottom contact involves the self-assembly of pillar structures on a metal surface. Two other methods involve the selective addition or removal of material through a suitable mask or template.

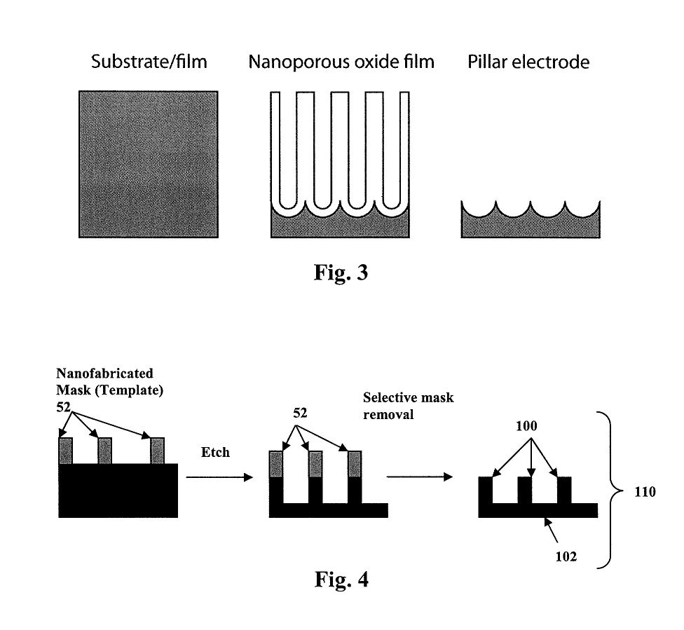

A method for forming structured pillar electrodes for the bottom contact will be described here with reference to FIG. 3. In this embodiment, the initial substrate is a flat piece of aluminum, although titanium or zinc would also be suitable. The aluminum substrate may be in either bulk form, as a foil sheet, a thin foil adhered to a backing material (e.g., glass or plastic), or a thin film deposited onto a backing material (e.g., glass or plastic). The initial aluminum substrate is first electrochemically anodized in the appropriate acidic electrolyte. Examples include sulfuric acid, oxalic acid, and phosphoric acid. Anodization of aluminum results in the growth of an aluminum oxide on the aluminum surface and, under suitable conditions, the aluminum oxide layer will comprise hexagonally packed nanoscale pores. The mean pore size and spacing are controlled by the anodization conditions (e.g., anodization potential). An example of this process is provided by Li, et al. in “Hexagonal Pore Arrays With a 50-420 nm Interpore Distance Formed by Self-Organization in Anodic Alumina,” Journal of Applied Physics 84, 6023-6026 (1998) which is incorporated by reference as if fully set forth in this specification. The porous aluminum oxide layer can be made with a high degree of uniformity, with pore size distributions on the order of 10 percent of the mean. The dimensions of representative achievable mean pore spacing (center-to-center distance) using this method is from around 50 nm to around 400 nm with mean pore diameters between around 10 nm to around 300 nm.

The resulting structure consists of an aluminum substrate having a porous aluminum oxide layer at the surface. The interface between the aluminum substrate and aluminum oxide layer is not flat, but rather comprises a scalloped surface having sharp tips whose height and separation are determined by the dimensions of the electrochemically formed aluminum oxide layer. The high electric field at the sharp tips of the electrode structure may be expected to result in more efficient carrier collection. The aluminum oxide layer can be selectively removed by either chemical means or plasma etching methods. As an example, phosphoric acid will selectively remove aluminum oxide without harming the underlying aluminum. Upon removal of the aluminum oxide layer, the surface of the underlying aluminum substrate is no longer flat, but rather exhibits a high density of regular aluminum tips protruding from the surface. For example, a porous aluminum oxide layer with 100 nm mean pore separation will result in an aluminum surface having a mean tip separation of 100 nm, with tip heights of approximately 50 nm. This surface may be used as a structured bottom electrode which is subject to further device processing in which an active layer is formed on the electrode. While aluminum is being disclosed as an example of a material suitable for producing the structured pillar electrodes of the present invention, those skilled in the art will appreciate that the invention is not limited to aluminum electrodes. Other suitable electrode metals such as titanium (Ti) and zinc (Zn) as well as various alloys of these metals may also be used without departing from the spirit and scope of the present invention.

A subtractive process will now be described with reference to FIG. 4. Initially a layer of the material which will constitute both the horizontal base (102) and structured pillars (100) is deposited onto a suitable substrate using any of a plurality of thin film growth techniques which are well-known in the art. This includes, for example, deposition techniques such as electroplating, thermal evaporation, sputtering, laser ablation of a target, chemical vapor deposition (CVD), or molecular beam epitaxy (MBE) from suitable gas precursors and/or solid sources. In one embodiment the overall thickness of the deposited layer is set to be equal to the combined thickness of the horizontal base (102) and the height of the structured pillars (100).

Growth of the electrode material is followed by the application of a suitable mask onto the surface of the thus-formed film. A mask may be formed, for example, by conventional photolithographic processes which involve the steps of depositing a layer of photoresist, curing the resist, exposing select regions to light, and then developing the resist. This resulting mask (52) covers or protects regions of the surface under which pillars are to be formed while leaving other regions exposed. The exposed regions can then be removed via a suitable wet or dry etching process. Examples of dry processes include reactive ion etching (RIE) or ion beam etching. Etching proceeds for a predetermined time period with the height (h) of the structured pillars (100) and thickness (t) of the horizontal base (102) being determined by the amount of material removed during etching. In an alternative embodiment the horizontal base (102) may be deposited first as a thin film having a predetermined thickness (t). A different material which will constitute the structured pillars (100) is then deposited onto the horizontal base (102) to a thickness (h) equal to the length of the to-be-formed pillars (100). The material for the horizontal base (102) may be selected such that it is resistant to the etching process used and, hence, serves as an etch stop during the etching step. Once etching has been completed the mask (52) is removed and structured pillar electrodes (110) having the desired structure, diameter (d), height (h), and spacing (w) are thereby produced.

Aside from use of a conventional photoresist and photolithographic processing, a suitable mask may be formed using any material or process which is well-known in the art. Other examples include the use of deoxyribonucleic acid (DNA), nanoparticles, or anodized aluminum oxide. These may also be patterned using, in addition to photolithography, other techniques such as electron beam lithography or ion beam lithography. In another embodiment the structured pillar electrodes (110) can be formed from polymer films which spontaneously self-assemble into a template having nanometer-scale dimensions. An example of this process is provided by K. W. Guarini, et al. in “Process Integration Of Self-Assembled Polymer Templates Into Silicon Nanofabrication” J. Vac. Sci. Technol. B 20, 2788 (2002), by C. T. Black, et al. in U.S. Patent Appl. Publ. No. 2004/0124092, and in U.S. Pat. No. 6,358,813 to Holmes, et al. all of which are incorporated by reference as if fully set forth in this specification. This process involves spin-coating a solution of a diblock copolymer onto a substrate. The thus-formed film preferably has a thickness of less than 45 nm to promote pore uniformity. The film is subsequently annealed to the desired temperature to induce phase segregation of the polymer blocks into self-assembled nanometer-scale regions. An aqueous solution is used to develop the mask by selectively removing only one polymer, leaving behind a nanoporous polymer film having a self-assembled pattern formed thereon.

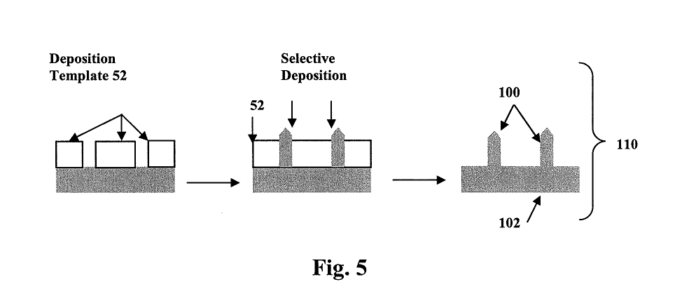

In another embodiment, material may be added through a suitable template (52) instead of removed. A typical addition process will now be described with reference to FIG. 5. Initially a thin film of material which will constitute the horizontal base (102) is deposited onto a suitable substrate. A mask or template (52) is then formed upon the horizontal base (102) using any of the deposition techniques which were described above with reference to the subtractive process in FIG. 4. The template (52) has a plurality of openings with the desired shape, cross-sectional diameter (d), and separation (w). Structured pillars (100) may be formed by deposition of the desired electrode material into the openings. In this case it is preferable for the thickness of the template (52) to be greater than the desired height (h) of the pillars (100). Deposition onto the template (52) can be controlled such that a film having a predetermined thickness is deposited into the open regions. The film thickness corresponds with the length (h) of the pillars (100). After deposition is complete the mask (52) may be removed by, for example, immersion in a suitable solvent. This leaves behind structured pillar electrodes (110) with a shape, cross-sectional diameter (d), and separation (w) defined by the openings in the mask and a pillar length (h) which is determined by the amount of material deposited.

In still another embodiment the structured pillars may be formed by the growth of nanowires on a suitable base. This may be accomplished, for example, by vapor-liquid-solid growth of electrically conductive nanowires. Another example involves the growth of carbon nanotubes from suitable catalyst particles dispersed on a base surface.

When structured pillar electrodes (110) are to be used as a top electrode, the fabrication process requires deposition directly onto the photoactive layer. In order to form the structured pillars (100) it is necessary to selectively remove or displace regions of the photoactive layer. In one embodiment this may be accomplished by, for example, using the subtractive process as detailed above. The position of each pillar (100) as well as its cross-sectional shape is defined by a suitable mask (52). The pillar (100) length is defined by the depth to which etching is performed. The electrode material may then be deposited directly into the etched trenches such that they are completely filled. The same template that was used to form the trenches may also be used as a mask during deposition of the pillars (100). In this case the structured pillars (100) may be formed first and, once completed, the mask (52) is removed by immersion in a suitable solvent. The base electrode (102) may then be formed by deposition of either the same or a different material. Alternatively, the mask (52) may be removed after etching and a base electrode (102) may be formed by simultaneous and continuous deposition into the etched trenches and onto the unetched surfaces of the photoactive layer to produce structured pillar electrodes (110).

In another embodiment the top structured pillar electrode (110) may be formed with a pillar “stamp”. The stamp has surface features which, when applied to the photoactive layer, leaves behind an imprint of the desired pattern directly onto the surface. The stamp may be formed, for example, from a Si substrate which has been sculpted using standard photolithography combined with Si etching and/or growth processes. The structure of the features on the stamp define the size, shape, and spacing of the pillars imprinted onto the photoactive layer. The top structured pillar electrode (110) may then be formed by deposition of a thin film using any thin film growth process such as those described above.

### IV. Advantages of Structured Pillar Electrodes

An optoelectronic device or, more specifically, a PV device fabricated with at least one structured pillar electrode offers several advantages over conventional devices. There are three primary advantages which arise from the use of structured pillar electrodes in optoelectronic devices. The first advantage is an improvement in the efficiency by which charge carriers are extracted. Since the structured pillars protrude into the photoactive layer, the distance a charge carrier must travel before arriving at an electrode is reduced. Rather than traveling across the entire thickness of the photoactive layer, the charge carriers only need to travel the pillar separation distance or, at most, half of the photoactive layer thickness before being collected by an electrode. Conventional organic bulk heterojunction PV devices typically have a thickness on the order of 100 to 200 nm. By using a bottom structured pillar electrode having pillars with a length which is half the photoactive layer thickness (e.g., 50 to 200 nm) and a separation of 20 to 30 nm, the average distance a charge carrier must travel before arriving at an electrode will be a fraction of that for a comparable organic PV device constructed with conventional planar electrodes. This reduction in travel distance increases the probability that generated charge carriers will be able to migrate to their respective electrode before recombination occurs.

A second advantage is the increase in contact area between the electrode and the photoactive layer. The overall increase in contact area depends primarily on the aspect ratio of the pillars. An increased contact area provides a larger surface over which charge carriers may be collected from the photoactive layer. A third advantage arises from the physical structure of the pillars. When a bulk heterojunction is formed on a base electrode having structured pillars, the presence of the pillars themselves spatially confines phase segregation during thermal annealing. Considering the length scales over which phase segregation occurs typically spans a distance of more than 100 nm, when the separation between structured pillars is smaller than this distance, segregation tends to be confined to regions located between each pillar. That is, the two-dimensional array of structured pillars acts as a template which directs phase segregation within the photoactive material. This can improve the carrier mobility in organic photoactive layers by affecting the chain conformation and conjugation length within polymers or the π-π stacking in small molecules.

Another important route through which structured pillars may improve the efficiency of PV devices is through an enhancement of the absorption of incident photons. The structured pillars provide a “roughened” interface which may, for example, result in diffuse scattering or may produce multiple internal reflections. These effects increase the probability that light will be absorbed by the photoactive layer and charge carriers will be generated. The structured pillars may also produce antenna and field effects at their tips which improve photon absorption through localized surface Plasmon resonance. This occurs when electromagnetic waves (e.g., from sunlight) are incident on a structured pillar electrode, the oscillating nature of the wave itself inducing motion of free charge carriers in the structured pillar or at its surface. This collective motion creates oscillating dipoles which may, in turn, re-emit electromagnetic waves whose wavelength is characteristic of the size, structure, and material comprising the pillars. The re-emitted light travels through the photoactive layer where it may be absorbed, thereby increasing the absorption probability. Furthermore, if plasmons are excited from closely spaced pillars, the strong electric field formed between individual pillars may aid in dissociation of the generated excitons.

### V. Exemplary Embodiments

Exemplary embodiments of the present invention will now be described in detail. In these embodiments, fabrication of PV devices comprising top and bottom nanostructured pillar electrodes and an organic bulk heterojunction formed between the electrodes, as illustrated in FIG. 2B will be described in detail.

In the first embodiment, the substrate (not shown) comprises an aluminum substrate, and pillar structures formed on the aluminum substrate using the combination of anodization and oxide-strip processing. First, the aluminum is anodized in 0.4 M oxalic acid solution at 40 V for 60 min to form self-assembled nanoporous anodic aluminum oxide with a 40 nm pore diameter, 100 nm pore spacing, and 12 μm thickness. The oxide layer is stripped using 5 weight % phosphoric acid at 60° C. for one hour. This produces an aluminum surface with a 50 nm tip height and 100 nm spacing. Immediately after oxide stripping, 2-5 nm of titanium is deposited by thermal evaporation to prevent the formation of a native surface oxide.

An organic bulk heterojunction may then be formed on the patterned Al surface by solution processing. A solution comprised of polythiophene and functionalized fullerene is spin-coated onto the thus-formed structured pillar electrode (110) at a spin speed of nominally 1000 rpm to form a 100 to 200 nm thick photoactive layer (104). After deposition, the photoactive layer (104) is annealed at 150° C. under a nitrogen argon-hydrogen ambient for a time period to produce the desired degree of phase segregation and, hence, create a bulk heterojunction. The PV device fabrication is completed by the formation of transparent top contact comprising ˜20-40 nm thick V₂O₅ and ˜80 nm thick ITO layers. The V₂O₅ layer is deposited on the bulk heterojunction (104) by thermal evaporation and is followed by sputter deposition of ITO.

In another embodiment, the top contact may be formed by a metal grid pattern made of Au. In this case the V₂O₅ layer is replaced by an approximately 100-nm-thick layer of PEDOT:PSS. This is accomplished by spin-coating PEDOT:PSS onto the bulk heterojunction layer at 2000 rpm prior to the deposition of Au metal grid pattern. The Au metal grid with a thickness of approximately 50 nm can be formed by thermal evaporation using a shadow mask.

In yet another embodiment, the substrate is comprised of a clean glass plate onto which a 100 to 200 nm-thick layer of ITO is deposited by sputter deposition to form the base electrode (102). ITO is chosen as the bottom electrode due to its high electrical conductivity and transparency. The ITO may be patterned into electrical contacts using standard photolithography or any other patterning technique which is well-known in the art.

Nanostructured pillar electrodes (110) are formed on the horizontal base electrode (102) by deposition through a patterned layer of photoresist. This template is formed by initially applying a thin film of photoresist to the surface by, for example, a spin-on technique. This is followed by a curing step which involves heating for a predetermined temperature and time period. The photoresist is then exposed through a reticle and, depending on the type of photoresist (positive or negative) and reticle used, the exposed areas either remain on the substrate or are removed by immersion in a suitable solvent. The patterned photoresist layer is then rinsed and dried. The thus-formed template has circular openings which are 30 nm in diameter and are arranged on the surface in a two-dimensional square lattice having a unit cell length of 50 nm between lattice points (e.g., the center-to-center pillar separation distance).

In another embodiment a patterned mask may be formed from diblock copolymers. In this embodiment a diblock copolymer consisting of polystyrene (PS) and polymethylmethacrylate (PMMA) dissolved in a solvent of toluene is spin-coated onto the surface of the base electrode to form a thin film. The film thickness is preferably less than 45 nm to ensure pore uniformity. The spun-on diblock copolymer film is subsequently annealed at 150° C. to 220° C. to induce microphase segregation of the polymer blocks. An aqueous develop is then applied to selectively remove one type of polymer and leave behind a porous polymer film which can be used as a template for the subsequent fabrication of structured pillars.

The nanostructured pillars (100) are formed by sputter depositing a 75-nm-thick thin film of ITO. The ITO is deposited into the openings in the templated photoresist layer. The photoresist is then removed by immersion in a suitable solvent. Dissolution of the photoresist removes ITO which was deposited on the surface of the photoresist itself via a lift-off process whereas material deposited through the openings in the photoresist remain on the surface. The result is a structured pillar electrode (110) comprised of a square lattice of columnar pillars having diameters of 30 nm, lengths of 75 nm, and center-to-center distances of 50 nm.

An organic bulk heterojunction is then formed by solution processing. A solution comprised of polythiophene and functionalized fullerene is spun-onto the thus-formed structured pillar electrode (110) at a spin speed of nominally 1000 rpm to form a 100 to 200 nm thick photoactive layer (104). After spin-on, the photoactive layer (104) is annealed at 150° C. under a nitrogen argon-hydrogen ambient for a time period to produce the desired degree of phase segregation and, hence, create a bulk heterojunction. The photoactive layer (104) may also be patterned and etched to constrain the thus-formed film to surface regions having a bottom nanostructured pillar electrode. The PV device is completed by formation of a top electrode comprised of a 100-nm-thick film of Al. The Al layer is deposited on the bulk heterojunction (104) by thermal evaporation The Al layer may also be suitably patterned and etched to form individual electrodes as well as the appropriate electrical wiring.

In still another embodiment, structured pillars may be formed in the top electrode using a stamp made of nanopillars. Before the top layer of Al is deposited, the blended photoactive layer can be embossed by the nanopillar stamp while the sample is heated or exposed to solvent vapors. This promotes the migration and flow of the organic material around the nanopillars on the stamp during the imprinting process. Once the annealing process is complete and the stamp is removed, the blended layer will comprise a series of recessed holes which correspond to the inverse of the nanopillar pattern on the stamp. Deposition of Al simultaneously fills the recessions (producing nanostructured pillars) and forms a top metallic contact.

During operation of the PV device, electromagnetic radiation is incident on the glass substrate on a side opposite the transparent ITO bottom nanostructured pillar electrode. The photon is scattered and subsequently absorbed by the photoactive layer to generate an exciton. The exciton then diffuses to the junction between acceptor and donor materials where it dissociates into free charge carriers. Electrons are transported to the donor material whereas holes are transported to the acceptor material. Electrons and holes subsequently travel through their respective donor and acceptor material until they reach the corresponding structured pillar electrode. Transport of charge carriers to their respective electrode may occur due to carrier diffusion or the band offset induced by the ITO and Al nanostructured pillar electrodes. This results in an electrical current which flows through the electrical circuit created by wiring connected to the top and bottom electrodes.

It will be appreciated by persons skilled in the art that the present invention is not limited to what has been particularly shown and described in this specification. Rather, the scope of the present invention is defined by the claims which follow. It should further be understood that the above description is only representative of illustrative examples of embodiments. For the reader's convenience, the above description has focused on a representative sample of possible embodiments, a sample that teaches the principles of the present invention. Other embodiments may result from a different combination of portions of different embodiments.

The description has not attempted to exhaustively enumerate all possible variations. The alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent. Furthermore, all references, publications, U.S. patents, and U.S. Patent Application Publications cited throughout this specification are incorporated by reference as if fully set forth in this specification.

What is claimed is:

1. An optoelectronic device comprising:
a photoactive layer having a heterojunction; and
at least one electrode which comprises an electrically conductive base and a plurality of electrically conductive pillars extending into the photoactive layer, the pillars being dispersed across a surface of the base.

2. The optoelectronic device of claim 1, further comprising at least two electrodes, each of said electrodes comprising an electrically conductive base and a plurality of electrically conductive pillars extending into the photoactive layer, the pillars being dispersed across a surface of the base.

3. The optoelectronic device according to claim 1, wherein the electrode is comprised of a metal.

4. The optoelectronic device according to claim 1, wherein the pillars and electrode are comprised of a metal.

5. The optoelectronic device according to claim 1, wherein the pillars and electrode are comprised of the same metal.

6. The optoelectronic device according to claim 1, wherein the metal is selected from the group consisting of Al, Ag, Au, Cu, Ca, Mg, In, Ga, and combinations thereof.

7. The optoelectronic device of claim 1, wherein the electrode is comprised of a material selected from the group consisting of indium tin oxide, indium tin oxide coated with poly(3,4-ethylenedioxythiophene: poly(styrene sulfate)), indium tin oxide coated with fluorinated tin oxide, aluminum zinc oxide, zinc oxide; titanium oxide, vanadium oxide, molybdenum oxide, gallium nitride, carbon nanotubes, silicon oxide coated with a transparent metal film, and combinations thereof.

8. The optoelectronic device according to claim 1, wherein the heterojunction is a bulk heterojunction, a planar heterojunction, or an ordered heterojunction.

9. The optoelectronic device according to claim 1, wherein the pillars are substantially equal in length, cross-sectional diameter, and shape.

10. The optoelectronic device according to claim 1, wherein said pillars have a cross-sectional shape which is selected from the group consisting of circular, elliptical, square, rectangular, pentagonal, hexagonal, and octagonal.

11. The optoelectronic device of claim 1, wherein the pillars are substantially perpendicular to a plane of the base.

12. The optoelectronic device of claim 1, wherein the height of the pillars is half the thickness of the photoactive layer.

13. The optoelectronic device of claim 1, wherein the height of the pillars is greater than or equal to 20 nm.

14. The optoelectronic device of claim 1, wherein the height of the pillars is less than or equal to 100 nm.

15. The optoelectronic device of claim 1, wherein the pillars are dispersed across the surface of the base in the form of a uniformly spaced two-dimensional array.

16. The optoelectronic device of claim 1, wherein the pillars are randomly dispersed across the surface of the base.

17. The optoelectronic device of claim 1, wherein the pillars are separated by a center-to-center distance of greater than or equal to 20 nm.

18. The optoelectronic device of claim 1, wherein the pillars are separated by a center-to-center distance which is less than or equal to 500 nm.

19. The optoelectronic device of claim 1, wherein the cross-sectional diameter of the pillars is greater than or equal to 10% of the thickness of the photoactive layer.

20. The optoelectronic device of claim 1, wherein the cross-sectional diameter of the pillars is less than or equal to 20% of the thickness of the photoactive layer.

21. The optoelectronic device of claim 1, wherein the cross-sectional diameter of the pillars is less than or equal to 30 nm.

22. The optoelectronic device of claim 1, wherein the cross-sectional diameter of the pillars is greater than or equal to 20 nm.

23. The optoelectronic device of claim 1, wherein at least one electrode is optically transparent.

24. The optoelectronic device of claim 1, wherein the electrical resistivity of the pillars is less than 10⁻⁴ Ohm-cm.

25. A method of forming an optoelectronic device having at least one structured pillar electrode comprising:
depositing a base layer onto a substrate;
creating a mask on the base layer;
forming pillars through openings in the mask; and
forming a film of a photoactive layer having a heterojunction on the base layer and the pillars.

26. The method of claim 25, wherein the step of forming the film of the photoactive layer is accomplished by solution processing.

27. The method of claim 25, wherein the step of creating the mask comprises forming a self-assembled polymer template using diblock copolymers.

28. The method of claim 25, wherein the step of creating the mask comprises patterning a layer of photoresist using photolithography.

29. The method of claim 25, wherein the step of creating the mask uses a process selected from the group consisting of electron beam lithography, dip-pen nanolithography, and ion beam lithography.

30. The method of claim 25, further comprising a step of removing the mask performed after the step of forming the pillars through openings in the mask and before the step of forming the film of the photoactive layer.

31. The method of claim 25, wherein the step of forming pillars comprises depositing a material into the openings in the mask.

32. The method of claim 25, wherein the step of forming pillars comprises etching away regions exposed by the openings in the mask.

33. A method of forming an optoelectronic device having at least one structured pillar electrode comprising:
depositing a bottom electrode onto a substrate;
forming a film of a photoactive layer having a heterojunction on the bottom electrode creating recessions in the photoactive layer;
forming pillars in the recessions; and
depositing a top electrode on the pillars and photoactive layer.

34. The method of claim 33, wherein the step of creating recessions in the photoactive layer comprises etching through a mask.

35. The method of claim 34, wherein the mask comprises a self-assembled polymer template formed from diblock copolymers.

36. The method of claim 34, wherein the mask comprises a layer of photoresist which has been patterned by photolithography.

37. The method of claim 34, wherein the mask is created using a process selected from the group consisting of electron beam lithography, dip-pen nanolithography, and ion beam lithography.

38. The method of claim 34, wherein a step of removing the mask is performed after the step of etching through the mask, but before the step of forming pillars in the recessions.

39. The method of claim 34, wherein a step of removing the mask is performed after the step of forming pillars in the recessions, but before the step of depositing the top electrode.

40. The method of claim 33, wherein the step of depositing a bottom electrode further comprises forming a plurality of pillars on a base.

41. The method of claim 33, wherein the step of creating recessions in the photoactive layer comprises imprinting a stamp having a pattern onto the photoactive layer.

42. The method of claim 33, wherein the step of forming the film of the photoactive layer is accomplished by solution processing.

43. The method of claim 33, wherein the step of forming the pillars comprises depositing a material into the recessions created in the photoactive layer.

44. A method of forming an optoelectronic device having at least one structured pillar electrode comprising:
depositing a bottom electrode onto a substrate;
anodizing a surface of the bottom electrode to form an oxidized surface layer comprising self-organized pores;
removing the oxidized surface layer such that structured pillars are dispersed across the surface of the bottom electrode; and
forming a film of a photoactive layer having a heterojunction on the bottom electrode.

45. The method of claim 44, wherein the surface of the bottom electrode is anodized electrochemically in an acidic electrolyte.

46. The method of claim 45, wherein the electrolyte is selected from the group consisting of sulfuric acid, oxalic acid, and phosphoric acid.

47. The method of claim 44, wherein the mean pore diameter is between 10 and 300 nm and the mean center-to-center pore separation is between 50 and 400 nm.

48. The method of claim 44, wherein the oxidized surface layer is removed by immersion in an acid which preferentially etches the oxidized surface layer over the bottom electrode.

49. The method of claim 44, wherein the oxidized surface layer is removed by etching in a plasma.

50. The method of claim 44, wherein the substrate comprises a metal selected from the group consisting of aluminum, titanium, and zinc.

51. The method of claim 44, wherein the oxidized surface layer is removed by exposure to phosphoric acid.

52. The method of claim 50, wherein the metal has an electrical resistivity of less than 10⁻⁴ Ohm-cm.

53. The method of claim 44, wherein a passivating surface layer is formed after the oxidized surface layer has been removed.

54. An optoelectronic device comprising:
at least one electrode which comprises an electrically conductive base and a plurality of electrically conductive pillars, the pillars being dispersed across a surface of the base and aligned substantially vertical relative to a plane of the surface of the base.

55. The optoelectronic device of claim 54, wherein the electrical resistivity of the pillars is less than 10⁻⁴ Ohm-cm.
